(19) United States
(12) Patent Application Publication
(10) Pub. No.: US 2025/0238057 A1
(43) Pub. Date: Jul. 24, 2025

(54) FOLDABLE SUPPORT DEVICE AND FOLDABLE DISPLAY DEVICE

(71) Applicants: Hefei Visionox Technology Co., Ltd., Hefei (CN); KunShan Go-Visionox Opto-Electronics Co., Ltd., Kunshan (CN)

(72) Inventors: Zhengyang LI, Hefei (CN); Yaling WANG, Hefei (CN); Fang ZHANG, Hefei (CN); Leichao ZHANG, Hefei (CN); Xiujian ZHU, Hefei (CN)

(73) Assignees: Hefei Visionox Technology Co., Ltd., Hefei (CN); KunShan Go-Visionox Opto-Electronics Co., Ltd., Kunshan (CN)

(21) Appl. No.: 19/180,145

(22) Filed: Apr. 16, 2025

Related U.S. Application Data
(63) Continuation of application No. PCT/CN2023/096399, filed on May 25, 2023.

(30) Foreign Application Priority Data
Nov. 24, 2022 (CN) 202211482290.9

(51) Int. Cl. G06F 1/16

(52) U.S. Cl. CPC G06F 1/1681; G06F 1/1652

(57) ABSTRACT

The present application provides a foldable support device and a foldable display device. The foldable support device includes two rotating members arranged adjacent to each other in a first direction, the two rotating members rotating synchronously, and each rotating member having a center of rotation; and two support members arranged on two sides of the two rotating members in the first direction, the two support members being correspondingly connected to the two rotating members, and the rotating member driving the support member to move, wherein during folding of the foldable support device, a distance between the centers of rotation of the two rotating members which rotate synchronously tends to decrease. Therefore, according to the foldable support device and the foldable display device provided by the present application, the crease of a flexible screen can be alleviated.

### CROSS REFERENCE TO RELATED APPLICATION

The present application is a continuation of International Application No. PCT/CN2023/096399, filed on May 25, 2023, which claims priority to Chinese Patent Application No. 202211482290.9, filed on Nov. 24, 2022 and entitled “FOLDABLE SUPPORT DEVICE AND FOLDABLE DISPLAY DEVICE”, all of which are incorporated herein by reference in their entireties.

### FIELD

The present application relates to the field of display, and in particular to a foldable support device and a foldable display device.

### BACKGROUND

Flexible display panels have special product forms such as folding, large angle bending, and rolling, and are used more and more.

For example, a foldable display panel can provide a larger display area in an unfolded state, and can occupy a smaller storage area in a folded state and is easy to carry, thereby receiving widespread attention. In the related art, a foldable display device may include a display panel and a foldable support device. The foldable support device is located on a backlight side of the display panel to support the display panel.

However, the crease of the display panel is severe.

### SUMMARY

In view of at least one of the above problems, embodiments of the present application provide a foldable support device and a foldable display device, which can alleviate the crease of a flexible screen to improve the display effect of the flexible screen and the foldable display device.

In order to achieve the above objective, the following solutions are provided by the embodiments of the present application.

In a first aspect of the embodiments of the present application, a foldable support device is provided. The foldable support device includes: two rotating members arranged adjacent to each other in a first direction, the two rotating members rotating synchronously, and each rotating member having a center of rotation; and two support members arranged on two sides of the two rotating members in the first direction, the two support members being correspondingly connected to the two rotating members, and the rotating members driving the support members to move, where during folding of the foldable support device, a distance between the centers of rotation of the two rotating members which rotate synchronously tends to decrease.

The foldable support device provided by the embodiments of the present application includes: two rotating members arranged adjacent to each other in a first direction, the two rotating members rotating synchronously, and each rotating member having a center of rotation; and two support members arranged on two sides of the two rotating members in the first direction and configured to support a flexible screen. The two support members are correspondingly connected to the two rotating members, and the rotating members drive the support members to move. During the folding of the foldable support device, a distance between the centers of rotation of the two rotating members which rotate synchronously tends to decrease, and during bending of the flexible screen, the bending radius of at least part of a bendable portion of the flexible screen increases, and the crease of the flexible screen can be alleviated.

In one embodiment, during the folding of the foldable support device, the distance between the centers of rotation of the two rotating members which rotate synchronously decreases gradually. In this way, during the bending of the flexible screen, the bending radius of at least part of the bendable portion of the flexible screen increases gradually, and the crease of the flexible screen can be alleviated.

It can be implemented that each of the rotating members is an involute gear, and the two rotating members which rotate synchronously mesh with each other.

As such, the involute gears are manufactured with a relatively mature process, and are simple to prepare.

In one embodiment, the foldable support device further includes an assembly member. The assembly member is provided with two first sliding channels spaced apart in the first direction, the first sliding channels extending obliquely in a thickness direction of the foldable support device, and the rotating members are each provided with a first sliding block, the first sliding blocks being correspondingly and slidably connected to the first sliding channels.

In this way, the distance between the centers of rotation of the two rotating members which rotate synchronously can be adjusted by means of the two first sliding channels.

In one embodiment, the support members are movably connected to the rotating members.

It can be implemented that the foldable support device further includes connecting members, and the support members are movably connected to the rotating members by means of the connecting members.

In one embodiment, the foldable support device further includes connecting members, each of which includes a first connecting end connected to the rotating member and a second connecting end connected to the support member.

It can be implemented that each of the support members is provided with a second sliding channel, and the second connecting end is slidably connected to the second sliding channel.

It can be implemented that a second elastic member is provided between an inner wall surface of the second sliding channel and the second connecting end.

In this way, it is possible to prevent the second connecting end from shaking.

In one embodiment, a second sliding block is provided at the second connecting end and is slidably connected to the second sliding channel.

It can be implemented that the second elastic member is provided between an inner wall surface of the second sliding channel and the second sliding block.

In one embodiment, each of the support members includes a fixed portion and a movable portion arranged in a thickness direction of the foldable support device, the movable portion being connected to the rotating member, the fixed portion being movably connected to the movable portion, the movable portion being movable relative to the fixed portion, and the movable portion having a support surface on a side facing away from the fixed portion.

It can be implemented that during the folding of the foldable support device, a distance between the fixed portion and the movable portion in the thickness direction decreases gradually.

It can be implemented that each of the support members is a planar support member.

In this way, when the foldable device is in a folded state, it is possible to prevent the portions of the flexible screen on the adjacent planar support members from squeezing each other due to an excessively small gap between the portions.

In one embodiment, the movable portion includes a first extension section and a second extension section which are connected to each other, the second extension section being connected to the rotating member, and the first extension section being connected to the second extension section by means of a first elastic member.

It can be implemented that in an arrangement direction of the first extension section and the second extension section, an extension length of the first extension section is greater than an extension length of the second extension section.

In this way, it is possible to prevent stress concentration caused by the first extension section pulling or squeezing the flexible screen during the folding.

In one embodiment, the foldable support device further includes a lifting assembly. The lifting assembly is arranged between the fixed portion and the movable portion and is configured to adjust the distance between the fixed portion and the movable portion in the thickness direction of the foldable support device.

It can be implemented that in the thickness direction of the foldable support device, a distance between the center of rotation and the fixed portion is greater than or equal to a distance between the support surface and the fixed portion.

It can be implemented that half of the distance between the centers of rotation of the two rotating members which rotate synchronously is a first value; in the thickness direction of the foldable support device, the distance between the center of rotation and the fixed portion minus the distance between the support surface and the fixed portion is a second value; and the sum of the first value and the second value remains the same during the folding of the foldable support device.

In this way, the movable portion can be driven by the lifting assembly to move closer to or away from the fixed portion.

In one embodiment, the lifting assembly includes a first lifting member, a second lifting member and a first driving member, the first driving member being connected to the first lifting member, the first lifting member fitting with the second lifting member, one of the first lifting member and the second lifting member being connected to the fixed portion, and the other of the first lifting member and the second lifting member being connected to the movable portion to drive the movable portion to move closer to or away from the fixed portion.

It can be implemented that the first lifting member fits with the second lifting member by means of threads or that the first lifting member fits with the second lifting member by means of toothed structures.

It can be implemented that the first lifting member has a through hole, the through hole has an internal thread on a hole wall surface, the second lifting member is inserted into the through hole and has an external thread on an outer wall surface, the internal thread is engaged with the external thread, and the first driving member is configured to drive the first lifting member to rotate.

It can be implemented that the first lifting member is a gear, the second lifting member is a rack, the gear meshes with the rack, and the first driving member is configured to drive the first lifting member to rotate.

In one embodiment, the second lifting member is connected to the fixed portion, the first lifting member is connected to the movable portion, and the first driving member drives the first lifting member to enable the first lifting member to drive the movable portion to move closer to or away from the fixed portion.

It can be implemented that the first lifting member has a through hole, the through hole has an internal thread on a hole wall surface, the second lifting member is inserted into the through hole and has an external thread on an outer wall surface, the internal thread is engaged with the external thread, and the first driving member is configured to drive the first lifting member to rotate, to enable the first lifting member to drive the movable portion to move closer to or away from the fixed portion.

In one embodiment, the lifting assembly includes a first connecting rod, a second connecting rod and a second driving member, where the first connecting rod is rotatably connected to the second connecting rod, a first end of the first connecting rod is connected to the movable portion, a second end of the first connecting rod is connected to the fixed portion, a third end of the second connecting rod is connected to the movable portion, and a fourth end of the second connecting rod is connected to the fixed portion; and

the second driving member is connected to at least one of the first connecting rod and the second connecting rod, and the first connecting rod and the second connecting rod drive the movable portion to move closer to or away from the fixed portion.

It can be implemented that the lifting assembly further includes a first linkage member and a second linkage member, where the first linkage member is connected to the first connecting rod or the second connecting rod, the second linkage member fits with the first linkage member, the second linkage member is connected to the second driving member, and the second driving member is configured to drive the second linkage member to move.

It can be implemented that the first linkage member is a rack, the second linkage member is a gear, the rack meshes with the gear, and the second driving member is configured to drive the gear to rotate.

A foldable display device is provided in a second aspect of the embodiments of the present application. The foldable display device includes a flexible screen, and a foldable support device in the first aspect, the foldable support device being configured to support the flexible screen.

The foldable display device provided by the embodiments of the present application may include a foldable support device. The foldable support device includes: two rotating members arranged adjacent to each other in a first direction, the two rotating members rotating synchronously, and each rotating member having a center of rotation; and two support members arranged on two sides of the two rotating members in the first direction and configured to support a flexible screen. The two support members are correspondingly connected to the two rotating members, and the rotating members drive the support members to move. During the folding of the foldable support device, a distance between the centers of rotation of the two rotating members which rotate synchronously tends to decrease, and during bending of the flexible screen, the bending radius of at least part of a bendable portion of the flexible screen increases, and the crease of the flexible screen can be alleviated.

The structure and other objectives and beneficial effects of the present application will become more apparent and easier to understand through the description of some embodiments with reference to the accompanying drawings.

### BRIEF DESCRIPTION OF THE DRAWINGS

To describe the embodiments of the present application or in the prior art more clearly, the drawings required for the descriptions of the embodiments or the prior art will be described briefly below. Apparently, the drawings in the following descriptions are illustrated for some of the embodiments of the present application.

FIG. 1 is a structural schematic diagram of a foldable support device in an unfolded state;

FIG. 2 is a structural schematic diagram of a foldable support device in a folded state;

FIG. 3 is a top view of a foldable support device and a housing according to an embodiment of the present application;

FIG. 4 is a top view of a foldable support device according to an embodiment of the present application;

FIG. 5 is a structural schematic diagram of a flexible screen in an unfolded state according to an embodiment of the present application;

FIG. 6 is a structural schematic diagram of a flexible screen in a folded state according to an embodiment of the present application;

FIG. 7 is another top view of a foldable support device according to an embodiment of the present application;

FIG. 8 is a structural schematic partial diagram of a foldable support device according to an embodiment of the present application;

FIG. 9 is another top view of a foldable support device according to an embodiment of the present application;

FIG. 10 is a cross-sectional view of a foldable support device according to an embodiment of the present application;

FIG. 11 is another cross-sectional view of a foldable support device according to an embodiment of the present application;

FIG. 12 is a structural schematic diagram of a foldable support device in a folded state according to an embodiment of the present application;

FIG. 13 is a structural schematic diagram of an assembly member and rotating members according to an embodiment of the present application;

FIG. 14 is a structural schematic diagram of the assembly member, the rotating members and connecting members according to an embodiment of the present application;

FIG. 15 is another structural schematic diagram of the assembly member and the rotating members according to an embodiment of the present application;

FIG. 16 is a structural schematic diagram of a rotating body according to an embodiment of the present application;

FIG. 17 is a top view of a second sliding channel according to an embodiment of the present application;

FIG. 18 is a cross-sectional view of the second sliding channel according to an embodiment of the present application;

FIG. 19 is a structural schematic diagram of a first extension section and a second extension section according to an embodiment of the present application;

FIG. 20 is a graph showing crease depths of flexible screens of a first example, a second example and a third example;

FIG. 21 is a graph showing first-order derivatives of the crease depths in FIG. 20;

FIG. 22 is a graph showing stress distribution of film layers in the flexible screens of the first example, the second example and the third example; and

FIG. 23 is a graph showing stress distribution of adhesive layers between the film layers in the flexible screens of the first example, the second example and the third example.

### DETAILED DESCRIPTION OF THE EMBODIMENTS

In the related art, a foldable display device may include a flexible screen and a foldable support device located on a backlight side of the flexible screen. The foldable support device supports the flexible screen. A user applies an external force to the foldable support device to enable the foldable support device to drive the flexible screen to be bent or unfolded.

As shown in FIG. 1, the foldable support device includes support members including a first planar support member 130A and a second planar support member 130B. The foldable support device includes a first gear 11 and a second gear 12. The first gear 11 is connected to the first planar support member 130A, the second gear 12 is connected to the second planar support member 130B, and the first gear 11 meshes with the second gear 12. The first planar support member 130A is rotatably connected to the second planar support member 130B by means of the first gear 11 and the second gear 12, and the first planar support member 130A and the second planar support member 130B can drive the flexible screen to be bent or unfolded. A spacing between the first planar support member 130A and the second planar support member 130B in a first direction X (i.e., a spacing between point D and point E in the first direction X in FIG. 1) corresponds to the size of a bendable portion of the flexible screen in the first direction X. The bendable portion of the flexible screen is bent during folding.

However, film layers of the bendable portion of the flexible screen are deformed under the external force, and the deformation recovery capability of each film layer is limited due to the material limitation. When the deformation of the film layers exceeds the limit of the deformation recovery capability, the deformation of the film layers is irreversible plastic deformation. After the external force is removed, the deformation cannot be eliminated, and the film layers cannot fully restore to their original shape. As a result, a crease may be formed in the bendable portion of the flexible screen, which in turn affects the display effect of the foldable display device.

Still referring to FIG. 1, a center of rotation of the first gear 11 is A, a center of rotation of the second gear 12 is B, and the distance between the center of rotation A and the center of rotation B is AB. In an example of the flexible screen which is positioned at point D (corresponding to a starting position for the bendable portion of the flexible screen), the distance between the center of rotation B and point D is BD, and the distance between the center of rotation B and a surface of a side of the second planar support member 130B facing the flexible screen is BC, where based on the Pythagorean theorem, BD²=BC²+CD². During bending of the flexible screen, BD may be regarded as a bending radius of the flexible screen positioned at point D. The smaller the length of BD, the smaller the bending radius of the flexible screen positioned at point D, the greater the deformation of and the larger the stress on the flexible screen positioned at point D during the bending are, resulting in severe crease. The larger the length of BD, the larger the bending radius of the flexible screen positioned at point D, the less the deformation of and the less the stress on the flexible screen positioned at point D during the bending are, and the crease of the flexible screen can be alleviated. The bending radii of other parts of the bendable portion of the flexible screen are similar to that of the flexible screen positioned at point D, which will not be repeated herein.

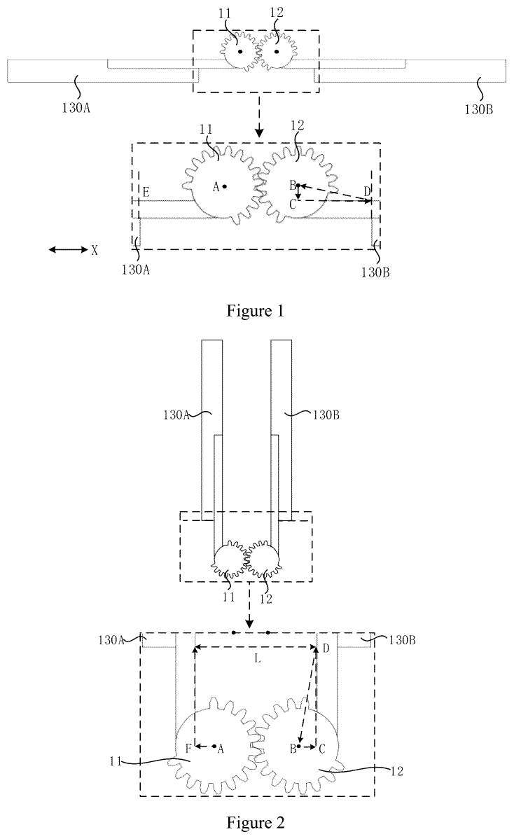

As shown in FIG. 2, when the first planar support member 130A and the second planar support member 130B are in a folded state, a distance between the first planar support member 130A and the second planar support member 130B is L, the distance L is the sum of a distance AF from the center of rotation A to a surface of a side of the first planar support member 130A facing the flexible screen, a distance BC from the center of rotation B to the surface of the side of the second planar support member 130B facing the flexible screen, and a distance AB between the center of rotation A and the center of rotation B, where AF may be equal to BC. That is, L=AF+AB+BC=AB+2BC. As shown in FIGS. 1 and 2, in the case of alleviating the crease by means of increasing BC while keeping CD fixed to increase BD, since the size of the bendable portion of the flexible screen in the first direction X in the unfolded state is fixed (DE is a constant value in the unfolded state), when CD is fixed, AB is fixed, and L increases, resulting in a widened gap between the portion of the flexible screen on the first planar support member 130A and the portion of the flexible screen on the second planar support member 130B in the folded state, which results in foreign objects easily entering the gap to cause wear on the flexible screen and also hinders the thinning and lightweight design of the foldable display device. In the case of alleviating the crease by means of increasing CD while keeping BC fixed to increase BD, since the size of the bendable portion of the flexible screen in the first direction X in the unfolded state is fixed (DE is a constant value in the unfolded state), when CD increases, AB decreases, and L decreases, resulting in a reduced gap between the portion of the flexible screen on the first planar support member 130A and the portion of the flexible screen on the second planar support member 130B in the folded state, which causes the portions the flexible screen to squeeze against each other, resulting in damage to the flexible screen.

In view of at least one of the above problems, the embodiments of the present application provide a foldable support device and a foldable display device. The foldable support device may be used for a flexible screen. The foldable support device includes: two rotating members arranged adjacent to each other in a first direction, the two rotating members rotating synchronously, and each rotating member having a center of rotation; and two support members arranged on two sides of the two rotating members in the first direction and configured to support a flexible screen. The two support members are correspondingly connected to the two rotating members, and the rotating members drive the support members to move respectively. During the folding of the foldable support device, a distance between the centers of rotation of the two rotating members which rotate synchronously tends to decrease, and during bending of the flexible screen, the bending radius of at least part of a bendable portion of the flexible screen tends to increase, and the crease of the flexible screen can be alleviated.

In order to make the embodiments of the present application clearer, the embodiments of the present application will be described clearly and completely below with reference to the accompanying drawings in the embodiments of the present application. Apparently, the embodiments described are some of, rather than all of, the embodiments of the present application.

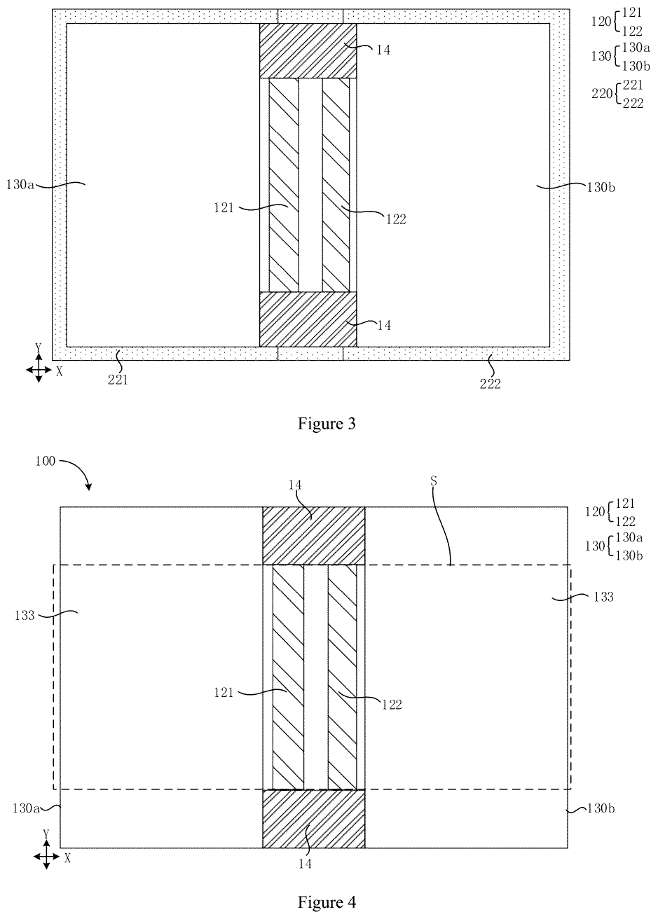

The foldable display device according to the embodiments of the present application is described below with reference to FIGS. 3 to 23.

The embodiments of the present application provide a foldable display device.

The foldable display device may be a mobile terminal or fixed terminal, such as electronic paper, a mobile phone, a tablet computer, a television, a laptop, a digital photo frame, a personal supercomputer, or a navigator. The foldable display device may include a flexible screen 210 and a foldable support device 100 located on a backlight side of the flexible screen 210.

As shown in FIGS. 3 to 5, the foldable display device may include a housing 220, a foldable support device 100 and a flexible screen 210. The flexible screen 210 may be fixed to the foldable support device 100, and the foldable support device 100 is located on the backlight side of the flexible screen 210. The foldable support device 100 may drive the flexible screen 210 to fold and support the flexible screen 210. The foldable support device 100 may be located in the housing 220, and the housing 220 is configured to protect the foldable support device 100. The flexible screen 210 may be directly fixed to the foldable support device 100, or the flexible screen 210 may be fixed to the foldable support device 100 by means of other structural members.

The flexible screen 210 according to the embodiments of the present application is described below.

The flexible screen 210 may be an organic light-emitting diode (OLED) display screen or a micro light-emitting diode (Micro LED) display screen.

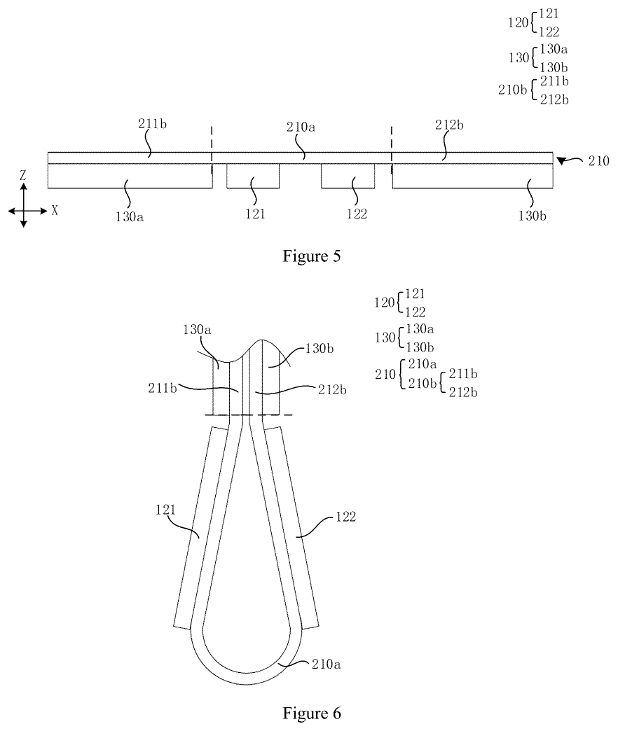

The flexible screen 210 may include a light-emitting side and a backlight side which are arranged opposite each other. The light-emitting side may be configured to display an image, and the backlight side is the side of the flexible screen 210 facing away from the light-emitting side. An upper side of the flexible screen 210 shown in FIG. 5 is the light-emitting side, and a lower side of the flexible screen 210 shown in FIG. 5 is the backlight side.

As shown in FIGS. 4, 5 and 6, the foldable display device has a first direction X, a second direction Y and a third direction Z. The first direction X, the second direction Y and the third direction Z are all different, and any two of them may be perpendicular to each other, for example. In the present application, the first direction X may be a width direction of the foldable display device, the second direction Y may be a length direction of the foldable display device, and the third direction Z may be a thickness direction of the foldable display device. The length, width, thickness, etc. in the embodiments of the present application are merely for ease of description and do not imply any limitation on dimensions. For example, the width may be greater than, equal to, or less than the length. The first direction X can be understood as corresponding to a linear direction when the product is unfolded, and corresponding to a curved direction when the product is folded.

As shown in FIGS. 5 and 6, the flexible screen 210 may include a bendable portion 210a and a non-bendable portion 210b arranged adjacent to each other. For example, the bendable portion 210a and the non-bendable portion 210b may be arranged adjacent to each other in the first direction X. At least one bendable portion 210a and at least one non-bendable portion 210b are provided, and one bendable portion 210a and one non-bendable portion 210b are arranged alternately. For example, the number of the bendable portions 210a may be one, two, three, or any number greater than three. The number of the non-bendable portions 210b may be one, two, three, or any number greater than three.

This embodiment of the present application is described by way of example in which the number of the bendable portions 210a is one, the number of the non-bendable portions 210b is two, and the two non-bendable portions 210b is connected by means of the bendable portion 210a.

The two non-bendable portions 210b may include a first non-bendable portion 211b and a second non-bendable portion 212b, and the bendable portion 210a is located between the first non-bendable portion 211b and the second non-bendable portion 212b. The bendable portion 210a can be bent and unfolded, thereby enabling the flexible screen 210 to be folded and unfolded.

The flexible screen 210 may be in an unfolded state, a folded state, or any intermediate state between the two states, and the state of the flexible screen 210 is also the state of the foldable support device 100 and the foldable display device. After the foldable support device 100 is connected to the flexible screen 210, the user applies a force to the foldable support device 100 through the housing 220 to enable the foldable support device 100 to drive the flexible screen 210 to be switched between the unfolded state and the folded state.

As shown in FIG. 5, the unfolded state refers to a state in which the portions of the flexible screen 210 are substantially in the same plane. In this case, the first non-bendable portion 211b, the second non-bendable portion 212b, and the bendable portion 210a are substantially in the same plane, and an angle between the first non-bendable portion 211b and the second non-bendable portion 212b is approximately 180 degrees. In the unfolded state, the flexible screen 210 has a relatively large display area, to ensure a better user experience.

As shown in FIG. 6, in the folded state, the bendable portion 210a of the flexible screen 210 is bent, the first non-bendable portion 211b and the second non-bendable portion 212b at least partially overlap in the thickness direction of the flexible screen 210, and the angle between the first non-bendable portion 211b and the second non-bendable portion 212b is approximately 0 degrees. In the folded state, the flexible screen 210 and the foldable display device having the flexible screen 210 occupy a small area, which facilitates storage and carrying of the foldable display device.

For example, the flexible screen 210 may be bent in a teardrop shape, and the distance between the first non-bendable portion 211b and the second non-bendable portion 212b in the folded state is small, which can prevent external foreign objects (such as dust) from entering the space between the first non-bendable portion 211b and the second non-bendable portion 212b of the flexible screen 210, thereby protecting the flexible screen 210.

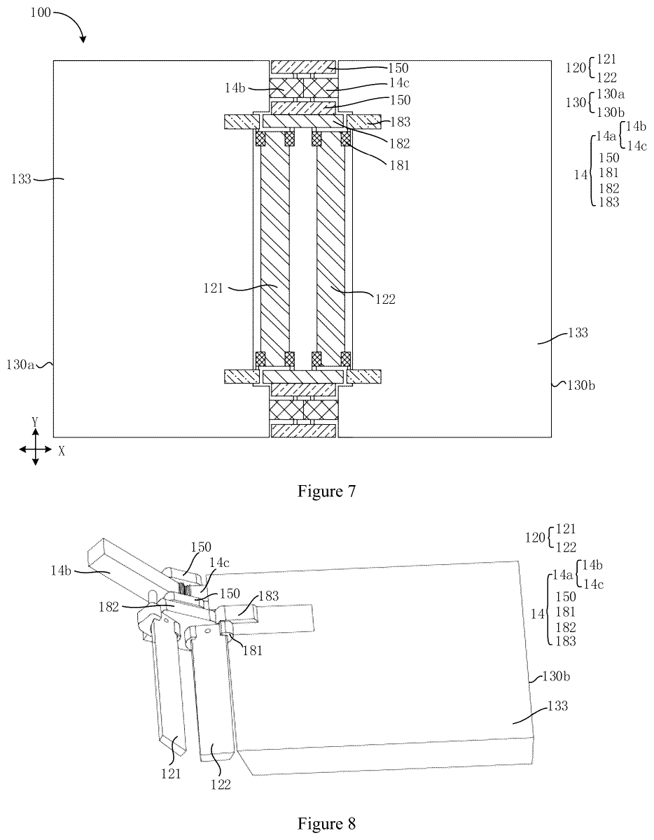

As shown in FIGS. 7 and 8, the side of the foldable support device 100 facing the flexible screen 210 has a support surface 133, and the support surface 133 is configured to fit with and be connected to the flexible screen 210.

In some embodiments, the foldable display device may be an inwardly foldable display device, that is, when the foldable display device is in a folded state, the folded flexible screen 210 is located inside the foldable support device 100, and the foldable support device 100 can protect the flexible screen 210. In this case, when the foldable display device is in the folded state, a display surface of the first non-bendable portion 211b and a display surface of the second non-bendable portion 212b are arranged facing each other.

In some embodiments, the foldable display device may be an outwardly foldable display device, that is, when the foldable display device is in a folded state, the folded flexible screen 210 is located outside the foldable support device 100, and the flexible screen 210 can implement a display function in the folded state to meet various display scenario requirements. In this case, when the foldable display device is in the folded state, the display surface of the first non-bendable portion 211b and the display surface of the second non-bendable portion 212b are arranged facing away from each other.

The foldable support device 100 according to the embodiments of the present application is described below.

The foldable support device 100 according to the embodiments of the present application is described in an example in which the number of the rotary support members 120 is two, the number of the planar support members 130 is two, and the two rotary support members 120 are located between the two planar support members 130.

Still referring to FIGS. 3 and 4, the housing 220 may include a first housing 221 and a second housing 222, the two planar support members 130 are a first planar support member 130a and a second planar support member 130b, the first planar support member 130a is fixed to the first housing 221, and the second planar support member 130b is fixed to the second housing 222. The two rotary support members 120 are a first rotary support member 121 and a second rotary support member 122.

As shown in FIGS. 5 and 6, the foldable support device 100 includes the first planar support member 130a, the first rotary support member 121, the second rotary support member 122, and the second planar support member 130b, which are arranged in sequence in the first direction X. The first rotary support member 121 and the second rotary support member 122 are provided between the first planar support member 130a and the second planar support member 130b. The first rotary support member 121 is arranged adjacent to the second rotary support member 122, and a gap is provided between the first rotary support member 121 and the second rotary support member 122. The first planar support member 130a is arranged corresponding to the first non-bendable portion 211b, and the second planar support member 130b is arranged corresponding to the second non-bendable portion 212b. The planar support members 130 are configured to fit with the non-bendable portions 210b of the flexible screen 210. The first rotary support member 121 and the second rotary support member 122 are arranged corresponding to one bendable portion 210a, and the first rotary support member 121 and the second rotary support member 122 are configured to fit with the bendable portion 210a of the flexible screen 210.

Referring to FIG. 4, the first planar support member 130a may be rotatably connected to the first rotary support member 121 by means of a connecting assembly 14, and the second planar support member 130b may also be rotatably connected to the second rotary support member 122 by means of a connecting assembly 14. During the folding of the foldable display device, the planar support members 130 and the rotary support members 120 always provide planar support for the flexible screen 210.

Still referring to FIGS. 7 and 8, the connecting assembly 14 includes two connecting structures 14a which are respectively connected to the first planar support member 130a and the second planar support member 130b. The two connecting structures 14a may be a first connecting structure 14b and a second connecting structure 14c. The first connecting structure 14b is connected to the first planar support member 130a, and the second connecting structure 14c is connected to the second planar support member 130b.

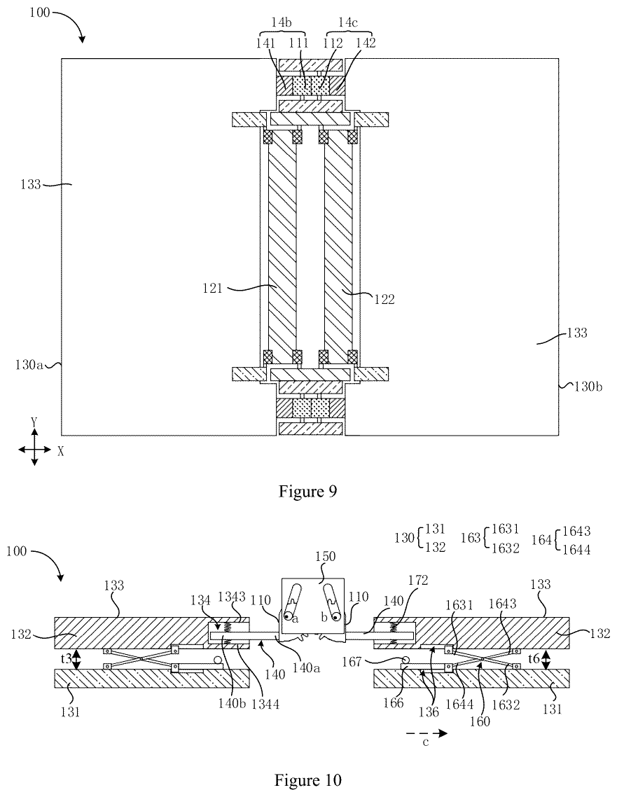

Referring to FIG. 9, the first connecting structure 14b includes a first connecting member 141 and a first rotating member 111 connected to the first connecting member 141, and the second connecting structure 14c includes a second connecting member 142 and a second rotating member 112 connected to the second connecting member 142. The first rotating member 111 is rotatably connected to the second rotating member 112. For example, the first rotating member 111 includes a first toothed structure 1111 (FIG. 15), the second rotating member 112 includes a second toothed structure 1121 (FIG. 15), and the first toothed structure 1111 and the second toothed structure 1121 mesh with each other to enable the first rotating member 111 and the second rotating member 112 to rotate synchronously. The first connecting member 141 and the first rotating member 111 may be arranged integrally or separately. Similarly, the second connecting member 142 and the second rotating member 112 may be arranged integrally or separately. The first rotating member 111 and the second rotating member 112 may also be referred to as rotating members 110, and the first connecting member 141 and the second connecting member 142 may also be referred to as connecting members 140.

Still referring to FIG. 7, for example, two first connecting structures 14b are connected to the first planar support member 130a, and the two first connecting structures 14b are arranged in the second direction Y. Similarly, two second connecting structures 14c are connected to the second planar support member 130b, and the two second connecting structures 14c are arranged in the second direction Y.

For example, the connecting assembly 14 may also include two first alignment members 181, a second alignment member 182 and two third alignment members 183. The first alignment members 181 may be correspondingly connected to the rotary support members 120, the second alignment member 182 may be connected to the housing 220, and the third alignment members 183 may be correspondingly connected to the planar support members 130. The first alignment members 181 are rotatably connected to the third alignment members 183, to enable the rotary support members 120 to be rotatably connected to the planar support members 130. The two rotary support members 120 are rotatably connected to the second alignment member 182 by means of the first alignment members 181, respectively, thereby enabling the two rotary support members 120 to rotate. The connecting assembly 14 may also include assembly members 150, and the assembly members 150 may be directly connected to the housing 220 or indirectly connected to the housing by means of other structural members. Both the planar support members 130 may be rotatably connected to the assembly members 150 by means of the connecting structures 14a (the first connecting structure 14b and the second connecting structure 14c), thereby enabling the two planar support members 130 to rotate.

Referring to FIG. 4, the side of the foldable support device 100 facing the flexible screen 210 has a flexible screen placement region S. The flexible screen placement region S is configured to correspond to the flexible screen 210, and the flexible screen placement region S is configured to place and support the flexible screen 210. At least part of the planar support members 130 and at least part of the rotary support member 120 are located in the flexible screen placement region S. In this way, the non-bendable portions 210b and the bendable portion 210a can all be supported. A dashed box S shows the flexible screen placement region, and an orthographic projection of the flexible screen 210 on a plane where the support surface 133 of the foldable support device 100 is located overlaps with the flexible screen placement region S. It should be understood that the flexible screen placement region S may also be larger or smaller than that shown as the dashed box S. For example, the connecting assembly 14 may be located outside the flexible screen placement region S, which can prevent the connecting assembly 14 from rubbing or squeezing against the flexible screen 210 during the folding to avoid damage to the flexible screen 210.

The planar support members 130 according to the embodiments of the present application are described below.

As shown in FIGS. 9 and 10, each planar support member 130 may include a fixed portion 131 and a movable portion 132 stacked in the thickness direction. The fixed portion 131 is located on the side of the movable portion 132 facing away from the flexible screen 210, and a surface of the side of the movable portion 132 facing away from the fixed portion 131 forms the support surface 133. The movable portions 132 of the planar support members 130 are connected to the connecting member 140, that is, the movable portions 132 are connected to the rotating members 110 by means of the connecting member 140. As shown in FIG. 10, the connecting member 140 may include a first connecting end 140a connected to the rotating members 110, and the connecting member 140 may further include a second connecting end 140b connected to the movable portions 132.

The fixed portion 131 may be connected to the housing 220 (FIG. 3), and the fixed portion 131 may be connected to the housing 220 by bonding, clamping, welding, threaded connection, integral forming, etc. The fixed portion 131 may be a part of the housing 220, or the fixed portion 131 and the housing 220 may be two structural members and connected together. When the fixed portion 131 is a part of the housing 220, the structure of the foldable display device can be simplified.

The movable portion 132 is movably arranged in the thickness direction of the foldable support device 100. In the same planar support member 130, the movable portion 132 may move closer to or away from the fixed portion 131 in the thickness direction of the planar support member 130 to adjust the distance between the movable portion 132 and the fixed portion 131.

As shown in FIG. 11, the first planar support member 130a may include a first fixed portion 1311 and a first movable portion 1321, and the second planar support member 130b may include a second fixed portion 1312 and a second movable portion 1322. The first movable portion 1321 is connected to the first rotating member 111 by means of the first connecting member 141, and the second movable portion 1322 is connected to the second rotating member 112 by means of the second connecting member 142.

The rotating member 110 may have a center of rotation, and still referring to FIG. 11, the first rotating member 111 has a first center of rotation a, and the first rotating member 111 rotates around the first center of rotation a. The second rotating member 112 has a second center of rotation b, and the second rotating member 112 rotates around the second center of rotation b. A distance between the first center of rotation a and the second center of rotation b is a first distance ab. In the thickness direction of the foldable support device 100, a distance between the first center of rotation a and the support surface 133 of the first movable portion 1321 is a second distance. The second distance is equal to a distance t1 between the first center of rotation a and the first fixed portion 1311 minus a distance t2 between the support surface 133 of the first movable portion 1321 and the first fixed portion 1311, that is, the second distance=t1−t2. The second distance may be adjusted by means of adjusting a distance t3 between the first movable portion 1321 and the first fixed portion 1311. When t3 decreases, t2 decreases, and the second distance increases. Here, t1 may be greater than or equal to t2, and the second distance may be greater than or equal to zero. In addition, a distance between the second center of rotation b and the support surface 133 of the second movable portion 1322 is a third distance. The third distance is equal to a distance t4 between the second center of rotation b and the second fixed portion 1312 minus a distance t5 between the support surface 133 of the second movable portion 1322 and the second fixed portion 1312, that is, the third distance=t4−t5. The third distance may be adjusted by means of adjusting a distance t6 between the second movable portion 1322 and the second fixed portion 1312. When t6 decreases, t5 decreases, and the third distance increases. Here, t4 may be greater than or equal to t5, and the third distance may be greater than or equal to zero.

As is known from the above related art, during the folding, the bending radius of at least part of the bendable portion 210a (FIG. 5) increases as the first distance ab decreases; and the bending radius of at least part of the bendable portion 210a increases as the second distance or the third distance increases. As t3 decreases, the second distance increases, and as t6 decreases, the third distance increases, that is, the bending radius of at least part of the bendable portion 210a increases as t3 or t6 decreases. In the embodiments of the present application, during the folding of the foldable support device 100, the first distance ab between the first center of rotation a and the second center of rotation b may tend to decrease, and the bending radius of at least part of the bendable portion 210a may tend to increase, and the crease of the flexible screen 210 can be alleviated. For example, the gradual decrease in the first distance ab between the first center of rotation a and the second center of rotation b may result in a gradual increase in the bending radius of at least part of the bendable portion 210a, and the crease of the flexible screen 210 can be alleviated. In addition, in the same planar support member 130, the distance between the fixed portion 131 and the movable portion 132 in the thickness direction of the planar support member 130 gradually decreases (i.e., t3 and t6 decrease). With such an arrangement, when the foldable support device 100 is in the folded state, it is possible to prevent the portions of the flexible screen 210 from squeezing against each other due to the gap between the portions of the flexible screen 210 on the first planar support member 130a and on the second planar support member 130b being too small due to t3 and t6 being fixed (equivalent to the second distance and the third distance being fixed) while only the first distance ab being reduced. It is also possible to prevent foreign objects from easily entering the gap and thus causing wear on the flexible screen due to the gap between the portions of the flexible screen 210 on the first planar support member 130a and on the second planar support member 130b being too large due to the first distance ab being fixed while only t3 and t6 being reduced (equivalent to increasing the second distance and the third distance).

For example, when the foldable support device 100 is switched between a folded state and an unfolded state, the sum of the first distance ab, the second distance and the third distance may remain the same. The second distance may be equal to the third distance, and the first rotating member 111 and the second rotating member 112 may have the same structure. In this case, when the foldable support device 100 is switched between the folded state and the unfolded state, the sum of the half (the first value) of the first distance ab and the second distance (the second value) remains the same, and the sum of the half of the first distance ab and the third distance (the second value) remains the same. In this way, when the foldable support device 100 is in the folded state, the gap between the flexible screen 210 on the first planar support member 130a and the flexible screen 210 on the second planar support member 130b is a constant value. In addition, it is possible to ensure the smoothness of lifting of the rotating member 110 during the folding of the foldable support device 100, and the flexible screen 210 has a superior bending stress condition.

The adjustment of the first distance ab during the folding of the foldable support device 100 according to the embodiments of the present application is described below.

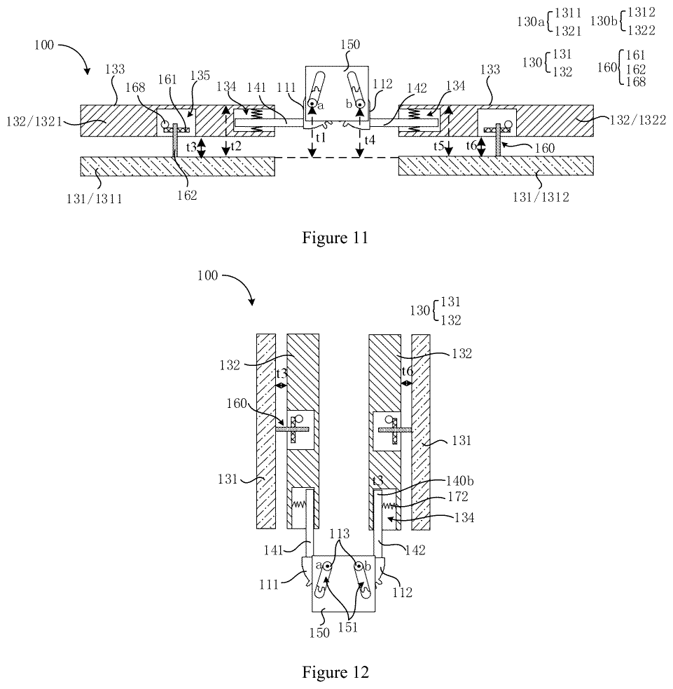

As shown in FIG. 12, the assembly member 150 is configured to assemble the first rotating member 111 and the second rotating member 112 which rotate synchronously. The assembly member 150 is provided with two first sliding channels 151 spaced apart in the first direction X (FIG. 9). The two first sliding channels 151 can be symmetrically arranged in the first direction X, the first sliding channels 151 extend obliquely in the thickness direction of the foldable support device 100, and the first rotating member 111 and the second rotating member 112 respectively slide along the two first sliding channels 151.

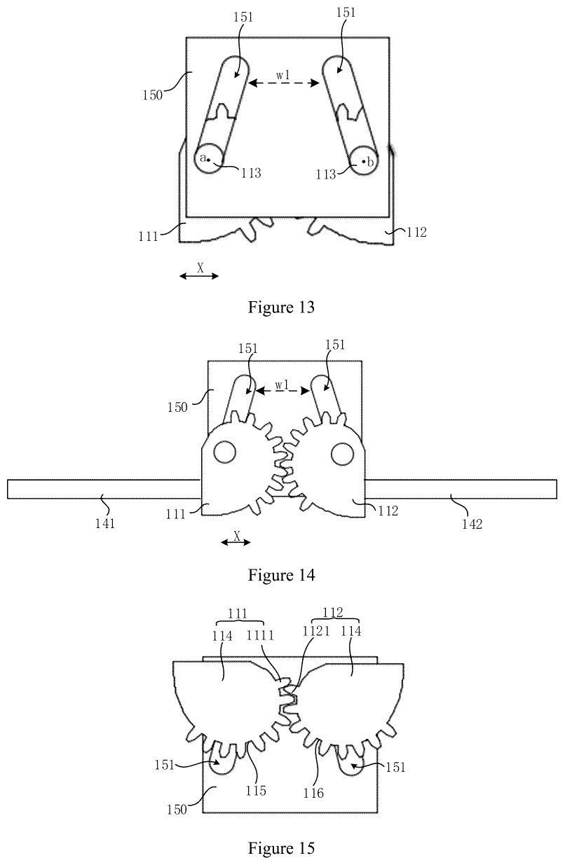

For example, as shown in FIGS. 13 and 14, each rotating member 110 is provided with a first sliding block 113, each first sliding block 113 is correspondingly and slidably connected to one first sliding channel 151, and the first sliding block 113 may also rotate in the first sliding channel 151. The first sliding block 113 of the first rotating member 111 is inserted into one of the first sliding channels 151 and slides in the first sliding channel 151. The first sliding block 113 of the second rotating member 112 is inserted into the other first sliding channel 151 and slides in the first sliding channel 151. The distance w1 between the two first sliding channels 151 in the first direction X decreases gradually in a direction from the fixed portion 131 to the movable portion 132 (i.e., in a direction from bottom to top in FIG. 13), and the ends of the first sliding channels 151 away from the fixed portion 131 (i.e., top ends in FIG. 13) are arranged obliquely toward the center of the assembly member 150. In this way, during the folding of the foldable support device 100, while the first rotating member 111 and the second rotating member 112 respectively slide from bottom to top along the two first sliding channels 151, the first rotating member 111 and the second rotating member 112 move closer to each other in the first direction X, and the first distance ab between the first center of rotation a and the second center of rotation b decreases gradually. During unfolding of the foldable support device 100, while the first rotating member 111 and the second rotating member 112 respectively slide from top to bottom along the two first sliding channels 151, the first rotating member 111 and the second rotating member 112 move away from each other in the first direction X, and the first distance ab between the first center of rotation a and the second center of rotation b increases gradually.

The assembly member 150 may be located on at least one side, in the second direction Y, of the corresponding two rotating members 110 which rotate synchronously. The assembly member 150 is located on one of the sides, in the second direction Y, of the corresponding two rotating members 110 (the first rotating member 111 and the second rotating member 112) which rotate synchronously. A smaller number of the assembly members 150 are provided, which can simplify the structure of the foldable support device 100. In the second direction Y, the flexible screen placement region S may be located on inner sides the two assembly members 150. In this way, it is possible to prevent the assembly members 150 from rubbing or squeezing against the flexible screen 210 during the folding to avoid damage to the flexible screen 210. As shown in FIG. 8, the assembly members 150 is located on two sides, in the second direction Y, of the corresponding two rotating members 110 which rotate synchronously, thereby providing better support for the two rotating members 110.

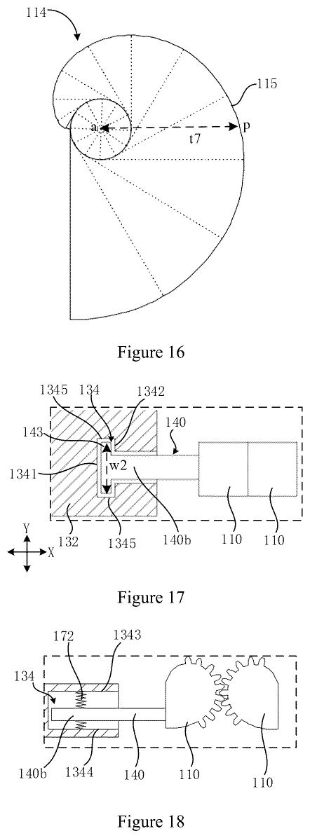

In an example of the first rotating member 111, as shown in FIGS. 15 and 16, the first rotating member 111 may include a rotating body 114 and a first toothed structure 1111. The first toothed structure 1111 is arranged on a first surface 115 of the rotating body 114. The first toothed structure 1111 at a first position P on the first surface 115 is engaged with the second rotating member 112, and a distance t7 between the first center of rotation a and the first position P decreases gradually during the folding of the foldable support device 100. In an example of the second rotating member 112, the second rotating member 112 may include a rotating body 114 and a second toothed structure 1121. The second toothed structure 1121 is arranged on a second surface 116 of the rotating body 114. The second toothed structure 1121 at a second position on the second surface 116 is engaged with the first rotating member 111, and the distance between the second center of rotation b and the second position decreases gradually during the folding of the foldable support device 100. In this way, during the folding of the foldable support device 100, it is possible to ensure the engagement between the first rotating member 111 and the second rotating member 112 while decreasing the first distance ab gradually, to achieve the synchronous rotation of the first rotating member 111 and the second rotating member 112.

For example, the first rotating member 111 and the second rotating member 112 may be two involute gears meshing with each other, which ensures the synchronous rotation of the first rotating member 111 and the second rotating member 112 while decreasing the first distance ab gradually. As shown in FIG. 16, the cross-section of the first surface 115 perpendicular to the planar support members 130 may be in the shape of an involute. In addition, the cross-section of the second surface perpendicular to the planar support members 130 may be in the shape of an involute.

The involute can be obtained by the way of fixing a circular shaft on a plane, wrapping a string around the circular shaft, tightening one string end, and moving the string around the circular shaft while remaining the string always tangent to the circular shaft, and the trajectory of a fixed point on the string on the plane is the involute.

The adjustment of the distance between the fixed portion 131 and the movable portion 132 of the same planar support member 130 in the thickness direction of the planar support member 130 according to the embodiment of the present application is described below.

Still referring to FIGS. 10 and 17, the second connecting end 140b of the connecting member 140 is movably connected to the movable portion 132 in the thickness direction of the planar support member 130. A second sliding channel 134 may be provided in the movable portion 132, a second sliding block 143 is provided at the second connecting end 140b, the second sliding block 143 is inserted into the second sliding channel 134, and the second connecting end 140b is slidably connected to the movable portion 132 by means of the second sliding channel 134 and the second sliding block 143. The second sliding channel 134 extends in the thickness direction of the planar support member 130, and the second sliding block 143 and the second sliding channel 134 move relatively in the thickness direction of the planar support member 130, to enable the movable portion 132 to move closer to or away from the fixed portion 131.

Still referring to FIG. 17, inner wall surfaces of the second sliding channel 134 include a first inner wall surface 1341 and a second inner wall surface 1342 arranged opposite each other and spaced apart in the first direction X. At least part of the second sliding block 143 is located between the first inner wall surface 1341 and the second inner wall surface 1342. The first inner wall surface 1341 is located on the side of the second sliding block 143 facing away from the rotating member 110, the second inner wall surface 1342 is located on the side of the second sliding block 143 facing the rotating member 110, and the first inner wall surface 1341 and the second inner wall surface 1342 are configured to limit the position of the second sliding block 143 in the first direction X to prevent the second sliding block 143 from separating from the movable portion 132. The connecting member 140 has a width w2 in the second direction Y. The width w2 of the second sliding block 143 may be greater than the width w2 of the rest part of the connecting member 140. The cross-sectional shape of the second sliding channel 134 is adapted to the cross-sectional shape of the second sliding block 143 to ensure the ability to assemble the second sliding block 143 and the second sliding channel 134. When the foldable support device 100 is switched between the unfolded state and the folded state, the connecting member 140 rotates around the center of rotation of the rotating member 110, and the second sliding block 143 is adapted to the second sliding channel 134 to enable the connecting member 140 to drive the movable portion 132 to rotate, that is, the movable portion 132 rotates around the center of rotation of the rotating member 110 by means of the connecting member 140.

As shown in FIG. 17, the inner wall surfaces of the second sliding channel 134 may include the first inner wall surface 1341 and the second inner wall surface 1342 arranged opposite each other and spaced apart in the first direction X and two fifth inner wall surfaces 1345 arranged opposite each other and spaced apart in the second direction Y. At least part of the fifth inner wall surfaces 1345 are located between the first inner wall surface 1341 and the second inner wall surface 1342.

As shown in FIG. 18, the inner wall surfaces of the second sliding channel 134 may also include a third inner wall surface 1343 and a fourth inner wall surface 1344 arranged opposite each other in the thickness direction of the planar support member 130. The third inner wall surface 1343 is located on the side of the fourth inner wall surface 1344 facing the flexible screen 210.

The foldable support device includes at least one second elastic member. A second clastic member 172 may be provided between an inner wall surface of the second sliding channel 134 and the second connecting end 140b. In some examples, as shown in FIG. 17, a second elastic member 172 may be provided between at least one of the first inner wall surface 1341, the second inner wall surface 1342 and the fifth inner wall surface 1345 (FIG. 17) and the second connecting end 140b. In an example of the first inner wall surface 1341, one end of the second elastic member 172 is connected to the second sliding block 143 of the second connecting end 140b, the other end of the second elastic member 172 abuts against the first inner wall surface 1341, and the second elastic member 172 may be in a compressed state. During sliding of the second sliding block 143, the second elastic member 172 is driven to move in the sliding direction, and the second elastic member 172 applies a pushing force to the second connecting end 140b, and the force is applied to both ends of the connecting member 140, which can prevent the second connecting end 140b from shaking. In one embodiment, the two ends of the second elastic member 172 are respectively connected to the second sliding block 143 and the first inner wall surface 1341, and during sliding of the second sliding block 143, the second elastic member 172 is compressed or stretched, and the second elastic member 172 applies a pushing force or a pulling force to the second connecting end 140b, and the force is applied to both ends of the connecting member 140, which can prevent the second connecting end 140b from shaking. When there is an assembly gap between the second sliding block 143 and the first inner wall surface 1341, the second elastic member 172 may be located in the assembly gap, which prevents the second sliding block 143 from moving along the assembly gap and thus prevents the second sliding block 143 from shaking. In other examples, a second elastic member 172 may be provided between at least one of the third inner wall surface 1343 and the fourth inner wall surface 1344 and the second connecting end 140b. In an example of the third inner wall surface 1343, one end of the second elastic member 172 may be connected to the second connecting end 140b by means of abutting, fixed connection to detachable connection, and the other end of the second elastic member 172 may be connected to the third inner wall surface 1343 by means of abutting, fixed connection to detachable connection. Since the first connecting end 140a receives a support force from the rotating member 110 and the assembly members 150, when there is no force applied to the second connecting end 140b, the second connecting end 140b will be in a free state and is prone to shaking in the assembly gap. Accordingly, the second elastic member 172 may be provided between the third inner wall surface 1343 and the second connecting end 140b. When the second connecting end 140b slides, the second elastic member 172 is compressed or stretched, and the second elastic member 172 applies a pushing force or a pulling force to the second connecting end 140b, and the force is applied to both ends of the connecting member 140, which can prevent the second connecting end 140b from shaking.

Still referring to FIG. 12, the foldable support device 100 may include a lifting assembly 160. The lifting assembly 160 is configured to adjust the distance (t3 or t6) between the movable portion 132 and the fixed portion 131 of the same planar support member 130 in the thickness direction of the planar support member 130 to adjust the distance (the second distance or the third distance) between the center of rotation of the rotating member 110 and the support surface 133 of the planar support member 130 correspondingly connected to the rotating member. The number of lifting assemblies 160 may be the same as the number of planar support members 130, and each lifting assembly 160 is correspondingly connected to one planar support member 130. During the folding of the foldable support device 100, when the foldable support device 100 is switched from the unfolded state to the folded state, the lifting assembly 160 is configured to adjust the distance between the fixed portion 131 and the movable portion 132 of the same planar support member 130 in the thickness direction of the planar support member 130 to decrease gradually. When the foldable support device 100 is switched from the folded state to the unfolded state, the lifting assembly 160 is configured to adjust the distance between the fixed portion 131 and the movable portion 132 of the same planar support member 130 in the thickness direction of the planar support member 130 to increase gradually.

The lifting assembly 160 according to the embodiment of the present application is described below.

Still referring to FIG. 11, the lifting assembly 160 may include a first lifting member 161 and a second lifting member 162. The first lifting member 161 may be connected to the movable portion 132, and the second lifting member 162 may be connected to the fixed portion 131. The movable portion 132 may have an accommodating cavity 135, and the first lifting member 161 is located in the accommodating cavity 135.

The lifting assembly 160 may also include a first driving member (not shown). The first driving member may be located in the accommodating cavity 135; the first driving member is connected to the first lifting member 161; the first driving member is configured to apply a driving force to drive the first lifting member 161 to move in the thickness direction of the planar support member 130 to enable the first lifting member 161 to drive the movable portion 132 to move closer to or away from the fixed portion 131, to adjust the distance between the movable portion 132 and the fixed portion 131.

For example, the first lifting member 161 may fit with the second lifting member 162 by means of threads to enable the first lifting member 161 to move in the thickness direction of the planar support member 130. A through hole may be provided in the first lifting member 161, the through hole has an internal thread on a hole wall surface, the second lifting member 162 is inserted into the through hole and has an external thread on an outer wall surface, and the internal thread is engaged with the external thread. The second lifting member 162 includes a fixed end connected to the fixed portion 131 and a free end inserted into the through hole. The first driving member may drive the first lifting member 161 to rotate to enable the first lifting member 161 to rotate relative to the second lifting member 162, and enable the first lifting member 161 to move in the thickness direction of the planar support member 130 by means of the engagement of the internal thread and the external thread, to enable the first lifting member 161 to drive the movable portion 132 to move closer to or away from the fixed portion 131.

In other embodiments, the first lifting member 161 may be connected to the fixed portion 131, and the second lifting member 162 may be connected to the movable portion 132. The fixed portion 131 may have an accommodating cavity 135, and the first lifting member 161 and the first driving member may be located in the accommodating cavity 135. The fixed end of the second lifting member 162 is connected to the movable portion 132, and the free end of the second lifting member 162 is inserted into the through hole of the first lifting member 161. The first driving member may drive the first lifting member 161 to rotate to enable the first lifting member 161 to rotate relative to the second lifting member 162, and enable the second lifting member 162 to move in the thickness direction of the planar support member 130 by means of the engagement of the internal thread and the external thread, to enable the second lifting member 162 to drive the movable portion 132 to move closer to or away from the fixed portion 131.

For example, the first driving member may be a micro motor. Still referring to FIG. 11, the lifting assembly 160 may include a fitting member 168. The fitting member 168 may be located in the accommodating cavity 135, the first driving member drives the fitting member 168 to rotate, and the fitting member 168 drives the first lifting member 161. The first lifting member 161 may be a gear, the fitting member 168 may fit with the gear, the first lifting member 161 meshes with the fitting member 168, and the first driving member drives the first lifting member 161 to rotate by means of the fitting member 168. The first lifting member 161 and the fitting member 168 may both be bevel gears, and a rotating shaft of the first driving member may be arranged parallel to the planar support member 130 to reduce the space occupied by the first driving member in the thickness direction of the planar support member 130, which reduces the impact on the thickness of the foldable display device.

Still referring to FIG. 11, the movable portion 132 may have an accommodating cavity 135, and the first lifting member 161 is located in the accommodating cavity 135, which reduces the impact on the thickness of the foldable display device, avoids the impact of the first lifting member 161 on the layout of other structural members, and reduces the volume occupied by the foldable support device 100. The first driving member may be located in the accommodating cavity 135, which avoids the impact of the first driving member on the layout of other structural members and reduces the impact on the thickness of the foldable display device. Of course, the first lifting member 161 or the first driving member may also be located outside the movable portion 132. Similarly, in other embodiments, the first lifting member 161 or the first driving member may also be located outside the fixed portion 131.

In other examples, the first lifting member 161 may fit with the second lifting member 162 by means of toothed structures. One of the first lifting member 161 and the second lifting member 162 may be connected to the fixed portion 131, and the other of the first lifting member 161 and the second lifting member 162 may be connected to the movable portion 132 to drive the movable portion 132 to move closer to or away from the fixed portion 131. The second lifting member 162 may be a rack which extends in the thickness direction of the planar support member 130. The first lifting member 161 may be a gear, the rack meshes with the gear, and the first driving member drives the gear to rotate. When the first lifting member 161 is connected to the movable portion 132 and the second lifting member 162 is connected to the fixed portion 131, the first driving member drives the first lifting member 161 to rotate. The fitting of the first lifting member 161 and the second lifting member 162 by means of the toothed structures enables the first lifting member 161 to move in the thickness direction of the planar support member 130 to enable the first lifting member 161 to drive the movable portion 132 to move closer to or away from the fixed portion 131. When the first lifting member 161 is connected to the fixed portion 131 and the second lifting member 162 is connected to the movable portion 132, the first driving member drives the first lifting member 161 to rotate. The fitting of the first lifting member 161 and the second lifting member 162 by means of the toothed structures enables the second lifting member 162 to move in the thickness direction of the planar support member 130 to enable the second lifting member 162 to drive the movable portion 132 to move closer to or away from the fixed portion 131.

Still referring to FIG. 10, the lifting assembly 160 may include a first connecting rod 163 and a second connecting rod 164. The first connecting rod 163 may be rotatably connected to the second connecting rod 164 by means of a connecting shaft, and the connecting shaft connects a middle section of the first connecting rod 163 and a middle section of the second connecting rod 164. Two ends of the first connecting rod 163 are a first end 1631 and a second end 1632, respectively. The first end 1631 is connected to the movable portion 132, and the second end 1632 is connected to the fixed portion 131. Two ends of the second connecting rod 164 are a third end 1643 and a fourth end 1644, respectively. The third end 1643 is connected to the movable portion 132, and the fourth end 1644 is connected to the fixed portion 131.

A second driving member (not shown) may be connected to one of the first connecting rod 163 and the second connecting rod 164, and the second driving member is configured to drive the first end 1631 and the fourth end 1644 to move in the first direction X; or the second driving member is configured to drive the second end 1632 and the third end 1643 to move in the first direction X.

In some examples, still referring to FIG. 10, the first end 1631 connected to the movable portion 132 slides in the first direction X, and the fourth end 1644 connected to the fixed portion 131 slides in the first direction X. The second driving member is connected to the fourth end 1644 and drives the fourth end 1644 to slide in the first direction X. The fixed portion 131 and the movable portion 132 may each be provided with a third sliding channel 136. The third sliding channels 136 extend in the first direction X, and the first end 1631 and the fourth end 1644 may be slidably connected to the third sliding channels 136. When the fourth end 1644 moves in a direction (i.e., direction c in FIG. 10) from the rotating member 110 to the planar support member 130, the first connecting rod 163 and the second connecting rod 164 rotate around the connecting shaft and drive the first end 1631 to move in the direction (i.e., direction c in FIG. 10) from the rotating member 110 to the planar support member 130. The distance between the first end 1631 and the fourth end 1644 increases, the distance between the second end 1632 and the third end 1643 increases, and the first connecting rod 163 and the second connecting rod 164 drive the movable portion 132 to move away from the fixed portion 131, to increase the distance between the movable portion 132 and the fixed portion 131. When the fourth end 1644 moves in a direction (i.e., opposite to direction c in FIG. 10) from the planar support member 130 to the rotating member 110, the first connecting rod 163 and the second connecting rod 164 rotate around the connecting shaft and drive the first end 1631 to move in the direction (i.e., opposite to direction c in FIG. 10) from the planar support member 130 to the rotating member 110. The distance between the first end 1631 and the fourth end 1644 decreases, the distance between the second end 1632 and the third end 1643 decreases, and the first connecting rod 163 and the second connecting rod 164 drive the movable portion 132 to move closer to the fixed portion 131, to reduce the distance between the movable portion 132 and the fixed portion 131. In one embodiment, the second driving member is connected to the first end 1631, the principle of which is similar to that of the second driving member being connected to the fourth end 1644, which will not be repeated herein. When a plurality of second driving members are provided in the lifting assembly 160, different second driving members may be respectively connected to the first end 1631 and the fourth end 1644, the principle of which has been explained and will not be repeated herein.

In other examples, the second end 1632 connected to the fixed portion 131 slides in the first direction X, and the third end 1643 connected to the movable portion 132 slides in the first direction X. The second driving member is connected to the second end 1632, or the second driving member is connected to the third end 1643. When a plurality of second driving members are provided in the lifting assembly 160, different second driving members may be respectively connected to the second end 1632 and the third end 1643, the principle of which has been explained and will not be repeated herein.

In other examples, the first end 1631 connected to the movable portion 132 slides in the first direction X, and the fourth end 1644 connected to the fixed portion 131 slides in the first direction X; and at the same time, the second end 1632 connected to the fixed portion 131 slides in the first direction X, and the third end 1643 connected to the movable portion 132 slides in the first direction X. A plurality of second driving members are provided, different second driving members may drive the first end 1631 and the fourth end 1644 to move in the first direction X and drive the second end 1632 and the third end 1643 to move in the first direction X, and the distance between the movable portion 132 and the fixed portion 131 can be adjusted more quickly.

For example, the second driving member may be a micro motor. An orthographic projection of the second driving member on the flexible screen 210 may be located at the non-bendable portion 210b (FIG. 5). The second driving member may be provided on the movable portion 132, or the second driving member may be provided on the fixed portion 131, or the second driving member may be provided on the housing 220 or other structural members. In one embodiment, the orthographic projection of the second driving member on the flexible screen 210 may also be located at the bendable portion 210a (FIG. 5).

For example, the lifting assembly 160 may also include a first linkage member 166 and a second linkage member 167. The first linkage member 166 extends in the first direction X and is movably arranged in the first direction X. The first linkage member 166 may be a rack, the second linkage member 167 may be a gear, and the rack meshes with the gear. The first linkage member 166 is connected to the first connecting rod 163 or the second connecting rod 164. In an example in which the first linkage member 166 is connected to the fourth end 1644, the second driving member is connected to the second linkage member 167, and the second driving member drives the second linkage member 167 to rotate, to drive the first linkage member 166 to move in the first direction X, and the first linkage member 166 drives the fourth end 1644 to move in the first direction X to enable the first connecting rod 163 and the second connecting rod 164 to drive the movable portion 132 to move closer to or away from the fixed portion 131, to enable the lifting assembly 160 to adjust the distance between the movable portion 132 and the fixed portion 131. When the orthographic projection of the second driving member on the flexible screen 210 is located at the bendable portion 210a (FIG. 5), two second linkage members 167 in two adjacent lifting assemblies 160 may mesh with each other, and the two second driving members in the two adjacent lifting assemblies 160 can be combined into one second driving member. The second driving member drives one of the second linkage members 167 to rotate and in turn drives the other second linkage member 167 to rotate, thereby simplifying the structure of the foldable support device 100. In addition, the first linkage member 166 may also fit with the second linkage member 167 by means of threads, and the first linkage member 166 is driven to move in the first direction X, the principle of which has been explained and will not be repeated herein.

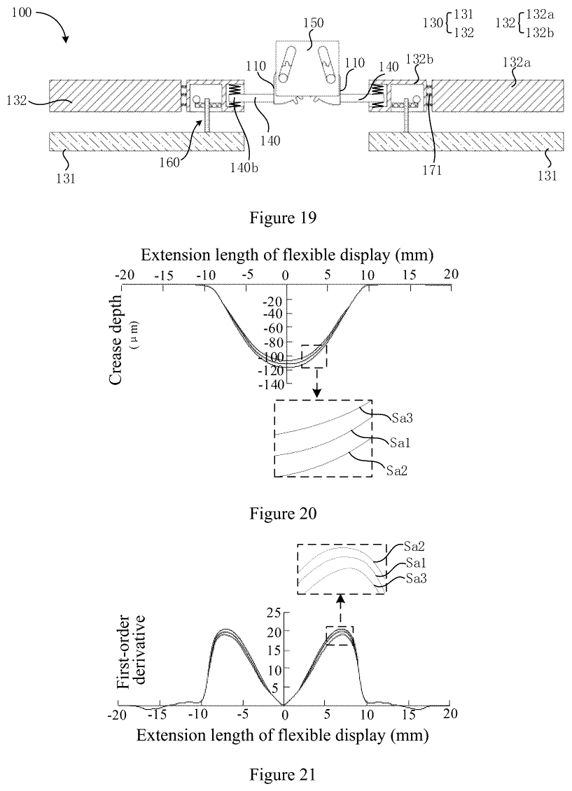

In some embodiments, as shown in FIG. 19, the movable portion 132 may include a first extension section 132a and a second extension section 132b which are connected together. The first extension section 132a is located on the side of the second extension section 132b facing away from the corresponding rotating member 110, and the second extension section 132b is located between the first extension section 132a and the rotating member 110. The first extension section 132a is configured to be connected to the flexible screen 210, and the second extension section 132b may not be connected to the flexible screen 210. The foldable support device includes at least two first elastic members 171. The first extension section 132a may be connected to the second extension section 132b by means of a first elastic member 171. During the bending of the flexible screen 210, the first extension section 132a applies a force to the bendable portion 210a, and the bendable portion 210a has a reaction force on the first extension section 132a. The first elastic member 171 may be deformed and there is a buffer space between the first extension section 132a and the second extension section 132b, the reaction force may drive the first extension section 132a to move closer to or away from the second extension section 132b to reduce the action force exerted by the first extension section 132a on the bendable portion 210a, which avoids stress concentration caused by the first extension section 132a pulling or squeezing against the flexible screen 210 during the folding to alleviate the crease of the bendable portion 210a, thereby prolonging the service life of the flexible screen 210.

The second extension section 132b may be movably connected to the connecting member 140, the lifting assembly 160 may be connected to the second extension section 132b, and the second extension section 132b moves closer to or away from the fixed portion 131 under the action of the lifting assembly 160, and drives the first extension section 132a by means of the first elastic member 171 to move synchronously in the thickness direction of the planar support member 130, to adjust the distance between the movable portion 132 and the fixed portion 131.

For example, in the first direction X, the extension length of the first extension section 132a is greater than the extension length of the second extension section 132b, resulting in a larger connection area between the first extension section 132a and the flexible screen 210, to achieve higher connection stability between the flexible screen 210 and the movable portion 132.

A first example Sa1, a second example Sa2 and a third example Sa3 are described below with reference to FIGS. 20 to 23.

In the first example Sa1, the first distance (ab in FIG. 11) is a first preset value, the second distance (t1−t2 in FIG. 11) is a second preset value, and the third distance (t4−t5 in FIG. 11) is a third preset value. In the second example Sa2, the first distance is 0.4 mm greater than the first preset value, the second distance is 0.2 mm less than the second preset value, and the third distance is 0.2 mm less than the third preset value. In the third example Sa3, the first distance is 0.4 mm less than the first preset value, the second distance is 0.2 mm greater than the second preset value, and the third distance is 0.2 mm greater than the third preset value. As can be seen from FIG. 20, the crease widths in Sa1, Sa2 and Sa3 are all 18.1 mm, the maximum crease depths in Sa1, Sa2 and Sa3 are approximately 114.2 μm, 118.7 μm, and 109.9 μm, respectively, and the crease depth of the flexible screen is Sa3<Sa1<Sa2. The improvement of the crease depth of the flexible screen in Sa3 compared with the crease depth of the flexible screen in Sa1 and the improvement of the crease depth of the flexible screen in Sa1 compared with the crease depth of the flexible screen in Sa2 are both about 4%, showing a noticeable improvement. As can be seen from FIG. 21, the maximum values of first-order derivatives of the crease depths Sa1, Sa2, and Sa3 are approximately 19.6, 20.5, and 18.9, respectively, and the first-order derivatives of the crease depths (i.e., the rate of change of the slope of creases) is Sa3<Sa1<Sa2. In summary, reducing the first distance and increasing the second distance and the third distance can reduce the crease depth of the flexible screen and the rate of change of the slope of the creases, and the crease of the flexible screen can be alleviated. The region between −10 mm and 10 mm can be referred to as the bendable portion of the flexible screen.

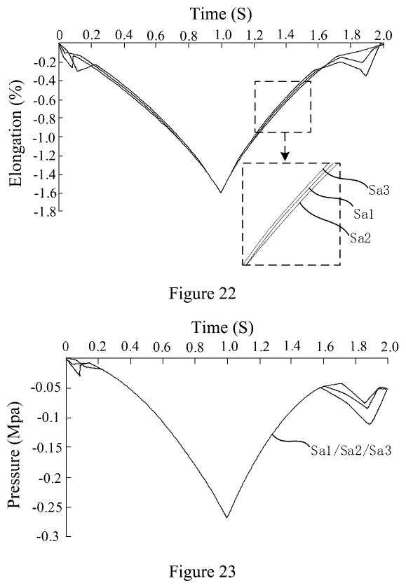

In FIGS. 22 and 23, the time period from 0 S to 1 S is for the bendable portion to switch from the unfolded state to the folded state, and the time period from 1 S to 2 S is for the bendable portion to switch from the folded state to the unfolded state. As can be seen from FIG. 22, the elongation of film layers (e.g., polarizers) in the flexible screen in Sa1, Sa2 and Sa3 is Sa3<Sa1<Sa2. As can be seen in FIG. 23, the pressures applied to adhesive layers between the film layers in the flexible screen in Sa1, Sa2 and Sa3 are substantially the same. In summary, reducing the first distance and increasing the second distance and the third distance can reduce the stress on the film layers at the bendable portion without affecting the stress on the adhesive layers between the film layers.

It should be noted here that the numerical values and ranges of numerical values referred to in the embodiments of the present application are approximate values, and there may be a range of errors as a result of the manufacturing process. These errors can be considered negligible in the art.

Finally, it should be noted that the above embodiments are merely used for illustrating rather than limiting the embodiments of the present application. Although the present application has been illustrated in detail with reference to the foregoing embodiments, it should be understood in the art that the solutions described in the foregoing embodiments may still be modified, or some or all of the technical features thereof may be equivalently substituted; and these modifications or substitutions do not make the essence of the corresponding solution depart from the scope of the embodiments of the present application.

What is claimed is:

1. A foldable support device, comprising:
two rotating members, arranged adjacent to each other in a first direction, the two rotating members rotating synchronously, and each rotating member having a center of rotation; and
two support members, arranged on two sides of the two rotating members in the first direction, the two support members being correspondingly connected to the two rotating members, and the rotating members driving the support members to move respectively,
wherein during folding of the foldable support device, a distance between the centers of rotation of the two rotating members which rotate synchronously tends to decrease.

2. The foldable support device according to claim 1, wherein during the folding of the foldable support device, the distance between the centers of rotation of the two rotating members which rotate synchronously decreases gradually.

3. The foldable support device according to claim 2, wherein each of the rotating members is an involute gear, and the two rotating members which rotate synchronously mesh with each other.

4. The foldable support device according to claim 2, further comprising an assembly member, wherein the assembly member is provided with two first sliding channels spaced apart in the first direction, the first sliding channels extending obliquely in a thickness direction of the foldable support device, and the rotating members are each provided with a first sliding block, the first sliding blocks being correspondingly and slidably connected to the first sliding channels.

5. The foldable support device according to claim 1, wherein the support members are movably connected to the rotating members respectively.

6. The foldable support device according to claim 5, further comprising two connecting members, wherein the support member is movably connected to the rotating member by means of the connecting member, and the connecting member comprises a first connecting end connected to the rotating member and a second connecting end connected to the support member.

7. The foldable support device according to claim 6, further comprising at least one second elastic member, wherein each of the support members is provided with a second sliding channel, the second connecting end is slidably connected to the second sliding channel, and the second elastic member is provided between an inner wall surface of the second sliding channel and the second connecting end.

8. The foldable support device according to claim 6, further comprising at least one second elastic member, wherein each of the support members is provided with a second sliding channel, the second connecting end is provided with a second sliding block, the second sliding block is slidably connected to the second sliding channel, and the second elastic member is provided between an inner wall surface of the second sliding channel and the second sliding block.

9. The foldable support device according to claim 1, wherein each of the support members comprises a fixed portion and a movable portion arranged in a thickness direction of the foldable support device, the movable portion being connected to the rotating member, the fixed portion being movably connected to the movable portion, the movable portion being movable relative to the fixed portion, and the movable portion having a support surface on a side facing away from the fixed portion.

10. The foldable support device according to claim 9, wherein during the folding of the foldable support device, a distance between the fixed portion and the movable portion in the thickness direction of the foldable support device decreases gradually.

11. The foldable support device according to claim 9, further comprising at least two first elastic members, wherein the movable portion comprises a first extension section and a second extension section which are connected to each other, the second extension section being connected to the rotating member, and the first extension section being connected to the second extension section by means of the first elastic member.

12. The foldable support device according to claim 11, wherein in an arrangement direction of the first extension section and the second extension section, an extension length of the first extension section is greater than an extension length of the second extension section.

13. The foldable support device according to claim 9, further comprising two lifting assemblies, wherein the lifting assembly is arranged between the fixed portion and the movable portion and is configured to adjust the distance between the fixed portion and the movable portion in the thickness direction of the foldable support device.

14. The foldable support device according to claim 13, wherein in the thickness direction of the foldable support device, a distance between the center of rotation and the fixed portion is greater than or equal to a distance between the support surface and the fixed portion.

15. The foldable support device according to claim 13, wherein half of the distance between the centers of rotation of the two rotating members which rotate synchronously is a first value; in the thickness direction of the foldable support device, the distance between the center of rotation and the fixed portion minus the distance between the support surface and the fixed portion is a second value; and a sum of the first value and the second value remains the same during the folding of the foldable support device.

16. The foldable support device according to claim 13, wherein the lifting assembly comprises a first lifting member, a second lifting member and a first driving member, the first driving member being connected to the first lifting member, the first lifting member fitting with the second lifting member, one of the first lifting member and the second lifting member being connected to the fixed portion, and the other of the first lifting member and the second lifting member being connected to the movable portion to drive the movable portion to move closer to or away from the fixed portion.

17. The foldable support device according to claim 16, wherein the first lifting member has a through hole, the through hole has an internal thread on a hole wall surface, the second lifting member is inserted into the through hole and has an external thread on an outer wall surface, the internal thread is engaged with the external thread, and the first driving member is configured to drive the first lifting member to rotate; or
wherein the first lifting member is a gear, the second lifting member is a rack, the gear meshes with the rack, and the first driving member is configured to drive the first lifting member to rotate.

18. The foldable support device according to claim 16, wherein the second lifting member is connected to the fixed portion, the first lifting member is connected to the movable portion, and the first driving member drives the first lifting member to enable the first lifting member to drive the movable portion to move closer to or away from the fixed portion.

19. The foldable support device according to claim 13, wherein the lifting assembly comprises a first connecting rod, a second connecting rod and a second driving member, wherein the first connecting rod is rotatably connected to the second connecting rod, a first end of the first connecting rod is connected to the movable portion, a second end of the first connecting rod is connected to the fixed portion, a third end of the second connecting rod is connected to the movable portion, and a fourth end of the second connecting rod is connected to the fixed portion; and
the second driving member is connected to at least one of the first connecting rod and the second connecting rod, and the first connecting rod and the second connecting rod drive the movable portion to move closer to or away from the fixed portion; and the lifting assembly further comprises a first linkage member and a second linkage member,
wherein the first linkage member is connected to the first connecting rod or the second connecting rod, the second linkage member fits with the first linkage member, the second linkage member is connected to the second driving member, and the second driving member is configured to drive the second linkage member to move; and the first linkage member is a rack, the second linkage member is a gear, the rack meshes with the gear, and the second driving member is configured to drive the gear to rotate.

20. A foldable display device, comprising:
a flexible screen, and a foldable support device, comprising:
two rotating members, arranged adjacent to each other in a first direction, the two rotating members rotating synchronously, and each rotating member having a center of rotation; and
two support members, arranged on two sides of the two rotating members in the first direction, the two support members being correspondingly connected to the two rotating members, and the rotating members driving the support members to move respectively,
wherein during folding of the foldable support device, a distance between the centers of rotation of the two rotating members which rotate synchronously tends to decrease, and
wherein the foldable support device being configured to support the flexible screen.
